(19) United States
(12) Patent Application Publication
(10) Pub. No.: US 2024/0212999 A1
(43) Pub. Date: Jun. 27, 2024

(54) SUBSTRATE TREATING APPARATUS AND SUBSTRATE TREATING METHOD

(71) Applicant: Semes Co., Ltd, Cheonan-si (KR)

(72) Inventors: Sung Hyuk JUNG, Suncheon-si (KR); Yong Seok JANG, Cheonan-si (KR)

(73) Assignee: Semes Co., Ltd, Cheonan-si (KR)

(21) Appl. No.: 18/394,805

(22) Filed: Dec. 22, 2023

(30) Foreign Application Priority Data
Dec. 27, 2022 (KR) 10-2022-0185931

(51) Int. Cl. H01J 37/32

(52) U.S. Cl. CPC H01J 37/32724; H01J 2237/184; H01J 2237/2007; H01J 2237/24585; H01L 21/6833

(57) ABSTRACT

Embodiments of the inventive concept provide a substrate treating apparatus and a substrate treating method for acquiring a temperature value in real time to apply to a process at a time point a process is completed, if measuring a temperature with respect to an electrostatic chuck (ESC) within a process chamber using a temperature analysis unit. The inventive concept provides a substrate treating apparatus. The substrate treating apparatus includes a process chamber including a housing at which a treating space is formed for process treating a substrate and a support unit positioned at the treating space and configured to support the substrate; and a temperature analysis unit configured to detect a temperature information of the support unit while mounted on the support unit and transmitting a detected temperature information to the process chamber, and wherein the process chamber controls a temperature of the support unit based on the temperature information.

### CROSS-REFERENCE TO RELATED APPLICATIONS

A claim for priority under 35 U.S.C. § 119 is made to Korean Patent Application No. 10-2022-0185931 filed on Dec. 27, 2022, in the Korean Intellectual Property Office, the entire contents of which are hereby incorporated by reference.

### TECHNICAL FIELD

Embodiments of the inventive concept described herein relate to a substrate treating apparatus and a substrate treating method, more specifically, a substrate treating apparatus and a substrate treating method for measuring a temperature of a substrate.

### BACKGROUND

An electrostatic chuck (ESC) installed in a semiconductor manufacturing process chamber serves to adsorb a substrate so that the substrate in the chamber does not move during a process.

Since the electrostatic chuck (ESC) is heated to a high temperature along with the substrate during the process, a temperature of an entire surface is uniformly adjusted by a cooling water and a heating body.

In this case, the electrostatic chuck (ESC) must measure a temperature to uniformly adjust an entire surface temperature, and a conventional temperature measurement method of the electrostatic chuck (ESC) transfers a dummy-type temperature measurement apparatus similar to a substrate from a non-vacuum input point to inside a process chamber in a vacuum state, and the temperature measurement apparatus measures the temperature of the electrostatic chuck. After measuring the temperature of the electrostatic chuck, the temperature measurement apparatus is taken out on a transfer path of the substrate, and then connected to a temperature analysis apparatus connected to a PC by an operator to analyze the temperature of the electrostatic chuck.

However, since the conventional temperature measurement method of the electrostatic chuck (ESC) is continuously transferred while including a temperature data until the temperature measurement apparatus is taken out, there is a problem that a wrong temperature data may be acquired by measuring the temperature of other elements aside from the electrostatic chuck on the transfer path.

Furthermore, the conventional temperature measurement method of the electrostatic chuck (ESC) has to connect a discharged dummy-type temperature measurement apparatus to a PC such as a laptop, analyze a distribution of temperature values or the like through a temperature analysis program, and input a set value into the process chamber to heat or cool the electrostatic chuck to an analyzed temperature. However, such an analysis process may derive different temperature values per operator if the temperature analysis process cannot be accurately controlled or if an operation error occurs.

In addition, since the conventional temperature measurement method of the electrostatic chuck (ESC) is manufactured according to a size of the substrate, a size of the temperature analysis unit must be changed according to the size of the substrate, so a temperature measurement cost increase.

### SUMMARY

Embodiments of the inventive concept provide a substrate treating apparatus and a substrate treating method for acquiring a temperature value in real time to apply to a process at a time point a process is completed, if measuring a temperature with respect to an electrostatic chuck (ESC) within a process chamber using a temperature analysis unit.

Embodiments of the inventive concept provide a substrate treating apparatus and a substrate treating method in which an analysis error does not occur by ensuring that a process of taking out a temperature analysis unit and analyzing a temperature is not performed by an operator.

Embodiments of the inventive concept provide a substrate treating apparatus and a substrate treating method for allowing a temperature analysis unit to be used together between substrates having different sizes.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a process chamber including a housing at which a treating space is formed for process treating a substrate and a support unit positioned at the treating space and configured to support the substrate; and a temperature analysis unit configured to detect a temperature information of the support unit while mounted on the support unit and transmitting a detected temperature information to the process chamber, and wherein the process chamber controls a temperature of the support unit based on the temperature information.

In an embodiment, the temperature analysis unit detects the temperature information while mounted on the treating space instead of the substrate.

In an embodiment, the support unit includes an electrostatic chuck for sucking the substrate with an electrostatic force, and wherein the temperature analysis unit detects the temperature information of the electrostatic chuck.

In an embodiment, the temperature analysis unit detects the temperature information of the electrostatic chuck by regions.

In an embodiment, the process chamber further includes a heating unit configured to heat the electrostatic chuck by regions, and wherein the temperature analysis unit transmits a detected temperature information to the heating unit, and the heating unit heats the electrostatic chuck by regions based on the temperature information.

In an embodiment, the process chamber blocks a communication between the temperature analysis unit positioned at the treating space and the process chamber when switching to a closed state.

In an embodiment, the temperature analysis unit includes: a temperature measurement module which measures a surface temperature of the support unit by regions while mounted on the support unit to detect the temperature information; and a temperature analysis unit configured to connect with the temperature measurement module to be input with the temperature information, to analyze an input temperature information by region to change to a temperature distribution information, and to transfer a changed temperature distribution information to the process chamber.

In an embodiment, the temperature measurement module includes: a temperature sensor disposed in a plurality which are spaced apart from one another; and a sensor side circuit board on which the temperature sensor is installed, on which a circuit pattern electrically connected to each of the temperature sensors is formed, and which is mounted on the support unit.

In an embodiment, the temperature sensor is chosen among any one of a surface elastic wave temperature sensor, an RTD sensor, or a thermistor.

In an embodiment, a portion of the plurality of the temperature sensors are set to measure a surface temperature of the support unit, and a portion of the temperature sensors aside from a temperature sensor measuring the surface temperature is set to measure an inner temperature of the support unit.

In an embodiment, the temperature analysis module includes: a temperature analysis circuit unit configured to electrically connect with the temperature sensors and analyze a temperature information detected by the temperature sensors to generate a temperature distribution information by regions of the support unit; a module side communication unit configured to connect with the temperature analysis circuit unit, to be input with the temperature distribution information from the temperature analysis circuit unit, and to wirelessly transmit an input temperature distribution information to the process chamber; a battery electrically connected to the temperature analysis circuit unit and the module side communication unit, and supplying a power to the temperature analysis unit circuit unit and the module side communication unit; and an analysis side circuit board on which the temperature analysis circuit unit, the module side communication unit and the battery are installed, and on which a circuit pattern electrically connecting the temperature analysis circuit unit, the module side communication unit, and the battery is formed.

In an embodiment, the temperature analysis module further includes a connection unit configured to electrically connect the analysis side circuit board and the temperature measurement module.

In an embodiment, the temperature analysis unit further includes a coupling body coupling the temperature measurement module and the temperature analysis unit in an attachable/detachable manner.

In an embodiment, the substrate treating apparatus further includes: a load port at which the temperature analysis unit is put; an atmospheric pressure transfer module positioned at a side of the load port and which transfers the temperature analysis unit within the load port in an atmospheric pressure state; a load lock chamber positioned at a side of the atmospheric pressure transfer module, which transduces an atmospheric pressure to a vacuum pressure, and forms a space at which the temperature analysis unit is transferred; and a vacuum transfer module which forms a vacuum pressure state, which transfers the temperature analysis unit positioned at the atmospheric pressure transfer module to the load lock chamber, and which mounts a transferred temperature analysis unit on the support unit of the process chamber, and wherein the sensor side circuit board further includes an putting direction confirmation region for checking an putting direction, the atmospheric pressure transfer module mounts the temperature analysis unit on the support unit so the putting direction confirmation region faces a certain direction, and the coupling body is disposed in a plurality and any one coupling method among the plurality is formed differently so the temperature measurement module and the temperature analysis module are coupled only at a specific position.

The inventive concept provides a substrate treating method. The substrate treating method includes mounting a temperature analysis unit instead of a substrate on a support unit of a process chamber; generating a temperature information by measuring a temperature of the support unit by the temperature analysis unit; generating a temperature distribution information by regions of the support unit by analyzing the temperature of the support unit by the temperature analysis unit; and transmitting the temperature distribution information to the process chamber.

In an embodiment, at the mounting the temperature analysis unit, the temperature analysis unit is put to the process chamber by going through a load port, an atmospheric pressure transfer module, a load lock chamber, and a vacuum transfer module.

In an embodiment, at the transmitting the temperature distribution information, the temperature distribution information is transmitted by performing a wireless communication with the process chamber, when the temperature analysis unit is positioned at the vacuum transfer module.

In an embodiment, the temperature analysis unit includes: a temperature measurement module generating the temperature information by measuring the temperature of the support unit; a temperature analysis module which is input with the temperature information, which analyzes the temperature distribution information by regions of the support unit, and which wirelessly transmits an analyzed temperature distribution information to the process chamber; and a coupling body which couples the temperature measurement module and the temperature analysis module, and wherein at the mounting the temperature analysis unit, the temperature measurement module is replaced and used according to a size of the support unit.

In an embodiment, the temperature analysis unit is driven by independently supplying a power by a battery while not connecting through a wire.

The inventive concept provides a substrate treating apparatus. The substrate treating apparatus includes a process chamber including a housing at which a treating space is formed for process treating a substrate, a support unit positioned at the treating space to support the substrate and including an electrostatic chuck for sucking the substrate, and a heating unit configured to heat the electrostatic chuck by regions based on a temperature information; and a temperature analysis unit configured to detect a temperature information of the electrostatic chuck by regions while mounted on the support unit, transmitting a detected temperature information to the process chamber, and detecting the temperature information while mounted in the treating space instead of the substrate; a load port at which the temperature analysis unit is put; an atmospheric pressure transfer module positioned at a side of the load port and which transfers the temperature analysis unit within the load port in an atmospheric pressure state; a load lock chamber positioned at a side of the atmospheric pressure transfer module, which transfers an atmospheric pressure to a vacuum pressure, and is a space at which the temperature analysis unit is transferred; and a vacuum transfer module which forms a vacuum pressure state, which transfers through the load lock chamber if the temperature analysis unit is positioned at the atmospheric pressure transfer module, and which mounts a transferred temperature analysis unit on the support unit of the process chamber so an putting direction confirmation region of the temperature analysis unit faces a certain direction, and wherein the temperature analysis unit includes: a temperature measurement module including a temperature sensor chosen among any one of a surface elastic wave temperature sensor, an RTD sensor, or a thermistor, disposed in a plurality which are spaced apart from one another, in which a surface temperature of the support unit is measured in regions to detect the temperature information, and a portion are set to measure the surface temperature of the support unit and at least another portion is set so an inner temperature of the support unit for measuring the surface temperature is set, and a sensor side circuit board on which the temperature sensor is mounted, on which a circuit pattern electrically connected to each of the temperature sensors is formed, on which the support unit is mounted, and on which an putting direction confirmation region to check an putting direction is formed; and a temperature analysis unit including a temperature analysis circuit unit configured to electrically connect with the temperature sensors and analyze a temperature information detected by the temperature sensors to generate a temperature distribution information by regions of the support unit, a module side communication unit configured to connect with the temperature analysis circuit unit, to be input with the temperature distribution information from the temperature analysis circuit unit, and to wirelessly transmit an input temperature distribution information to the process chamber, a battery electrically connected to the temperature analysis circuit unit and the module side communication unit, and supplying a power to the temperature analysis unit circuit unit and the module side communication unit, and an analysis side circuit board on which the temperature analysis circuit unit, the module side communication unit and the battery are installed, and on which a circuit pattern electrically connecting the temperature analysis circuit unit, the module side communication unit, and the battery is formed, a connection unit configured to electrically connect the analysis side circuit board and the temperature measurement module, and a coupling body coupling the temperature measurement module and the temperature analysis unit in an attachable/detachable manner, which is disposed in a plurality and any one coupling method among the plurality is formed differently so the temperature measurement module and the temperature analysis module are coupled only at a specific position.

According to an embodiment of the inventive concept, since a temperature distribution information can be acquired in real time at a time point a process is completed to apply to a process, an analysis time for analyzing a temperature of an electrostatic chuck may be greatly reduced, and a data error possibility may be greatly reduced.

According to an embodiment of the inventive concept, an analysis error by a user may be prevented because a temperature analysis unit independently analyses without taking out the temperature analysis unit so an operator can analyze a temperature.

According to an embodiment of the inventive concept, a temperature measurement module may be changed depending on a size of an electrostatic chuck which is a support unit and used, so an applicability may be increased and a temperature measurement cost may be reduced.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view schematically illustrating a substrate treating apparatus according to an embodiment of the inventive concept.

FIG. 2 is a side cross-sectional view of a process chamber according to an embodiment of FIG. 1 when viewed from a side direction.

FIG. 3 is a side view of a temperature analysis unit shown in FIG. 2.

FIG. 4 is a bottom view of the temperature analysis unit shown in FIG. 3.

FIG. 5 is a flowchart illustrating an electrical connection of the temperature analysis unit shown in FIG. 3.

FIG. 6 is a side view of a state in which a temperature measurement module and the temperature analysis module shown in FIG. 3 are decomposed by different coupling methods.

FIG. 7 is a side view of a state in which the temperature measurement module and the temperature analysis module shown in FIG. 6 are decomposed by different coupling methods.

FIG. 8 is a flowchart of a substrate treating method according to an embodiment of the inventive concept.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

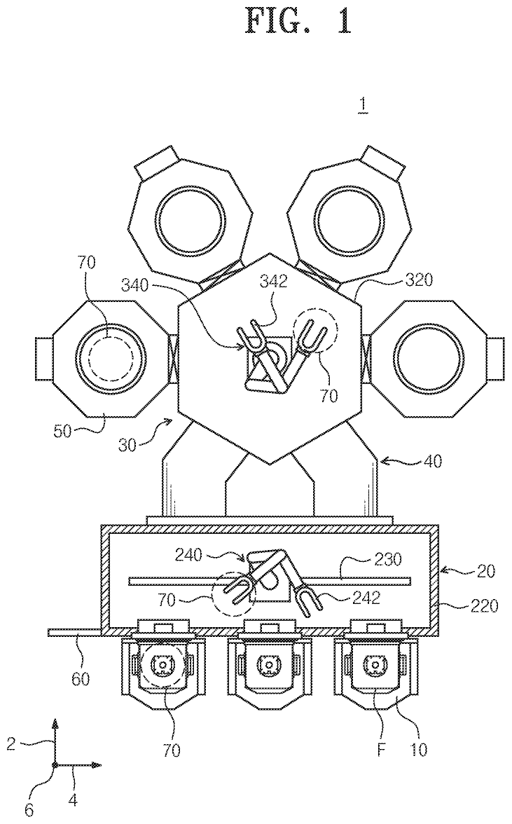

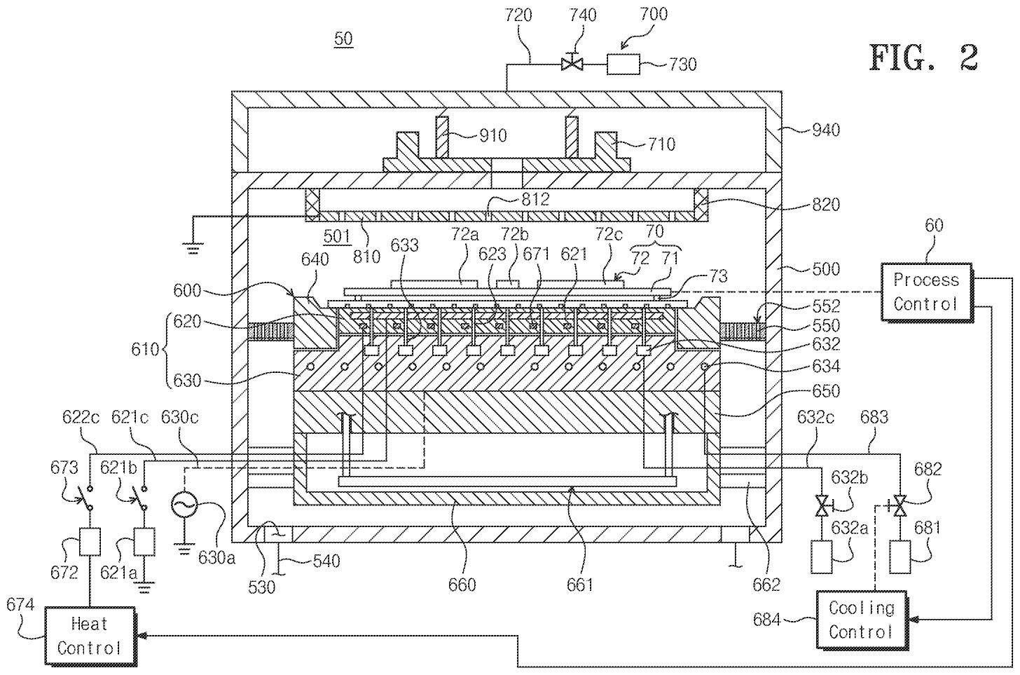

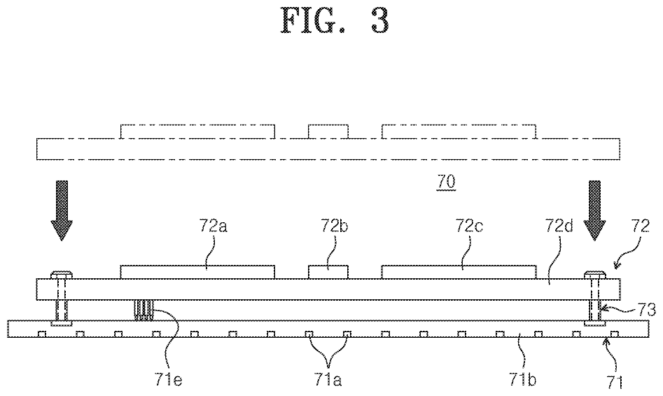

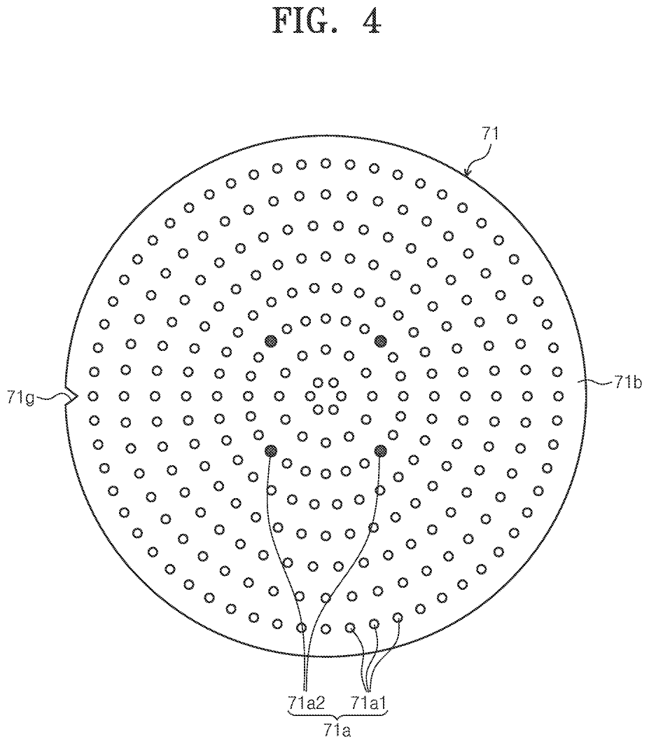

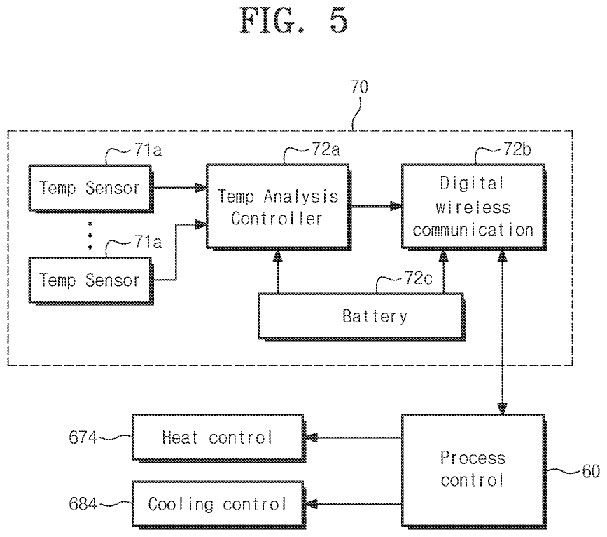

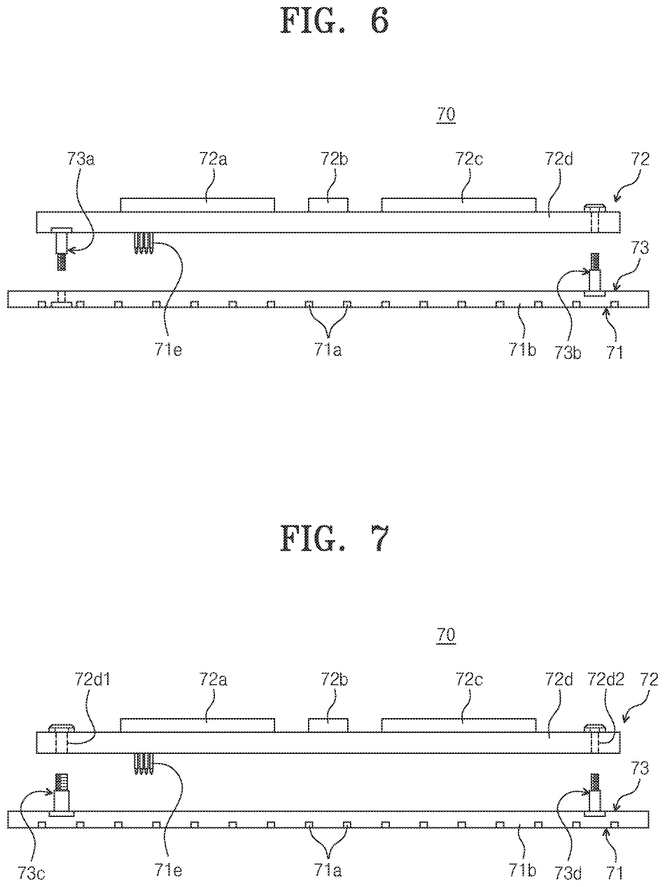

FIG. 1 is a plan view schematically illustrating a substrate treating apparatus according to an embodiment of the inventive concept. FIG. 2 is a side cross-sectional view of a process chamber according to an embodiment of FIG. 1 when viewed from a side direction. FIG. 3 is a side view of a temperature analysis unit shown in FIG. 2. FIG. 4 is a bottom view of the temperature analysis unit shown in FIG. 3. FIG. 5 is a flowchart illustrating an electrical connection of the temperature analysis unit illustrated in FIG. 3. FIG. 6 is a side view of a state in which a temperature measurement module and the temperature analysis module shown in FIG. 3 are decomposed by different coupling methods. FIG. 7 is a side view illustrating a state in which the temperature measurement module and the temperature analysis module shown in FIG. 6 are decomposed by different coupling methods.

Referring to FIG. 1 to FIG. 7, the substrate treating apparatus 1 according to an embodiment of the inventive concept may include a load port 10, an atmospheric pressure transfer module 20, a vacuum transfer module 30, a load lock chamber 40, a process chamber 50, a process control unit 60, and a temperature analysis unit 70.

The load port 10 may be disposed on a side of the atmospheric pressure transfer module 20 to be described later. At least one load port 10 may be disposed on a side of the atmospheric pressure transfer module 20. The number of load ports 10 may increase or decrease depending on a process efficiency and footprint conditions.

The container F may be placed in the load port 10. The container F may be loaded into the load port 10 or unloaded from the load port 10 by a means of transport (not shown) such as an overhead transfer apparatus (OHT), an overhead conveyor, or an automatic guided vehicle or an operator. The container F may include various types of containers depending on a type of articles to be stored. The container F may be a sealed container such as a front opening unified pod (FOUP).

The atmospheric pressure transfer module 20 and the vacuum transfer module 30 may be disposed along a first direction 2. Here, the first direction 2 is perpendicular to a second direction 4, and a surface including the first direction 2 and the second direction 4 is defined as a plane parallel to the ground. In addition, a direction perpendicular to a plane including the first direction 2 and the second direction 4 will be defined as a third direction 6. In addition, a surface including the second direction 4 and the third direction 6 is defined as a front surface, a surface including the first direction 2 and the third direction 6 is defined as a left side surface, and a set of six views is defined based on the front surface, the plane, and the left side surface. In this case, the terms of a top and a bottom will be described based on the third direction 6 perpendicular to the plane.

The atmospheric pressure transfer module 20 may transfer the substrate (not shown) between the container F and the load lock chamber 40 to be described later. According to an embodiment, the atmospheric pressure transfer module 20 may take out the substrate from the container F and transfer the substrate to the load lock chamber 40, or may take out the substrate from the load lock chamber 40 and transfer the substrate to an inside of the container F. Here, the substrate (not shown) may be configured as a wafer for a semiconductor process treatment.

The atmospheric pressure transfer module 20 may include a transfer frame 220 and a first transfer robot 240. The transfer frame 220 may be disposed between the load port 10 and the load lock chamber 40. The load port 10 may be connected to the transfer frame 220. An atmosphere within the transfer frame 220 may maintain an atmospheric pressure. According to an embodiment, an inside of the transfer frame 220 may be formed in the atmospheric pressure atmosphere.

The transfer rail 230 is disposed on the transfer frame 220. A lengthwise direction of the transfer rail 230 may be horizontal to a lengthwise direction of the transfer frame 220. The first transfer robot 240 may be positioned on the transfer rail 230.

The first transfer robot 240 may transfer the substrate between the container F seated on the load port 10 and the load lock chamber 40 to be described later. The first transfer robot 240 may forwardly and backwardly move in the second direction 4 along the transfer rail 230. The first transfer robot 240 may move in a vertical direction (e.g., the third direction 6). The first transfer robot 240 has a first transfer hand 242 which forwardly moves, backwardly moves, or rotates on a horizontal plane. The substrate is placed on the first transfer hand 242. The first transfer robot 240 may have a plurality of first transfer hands 242. The plurality of first transfer hands 242 may be disposed to be spaced apart from each other in the vertical direction.

The vacuum transfer module 30 may be disposed between the load lock chamber 40 and the process chamber 50 to be described later. The vacuum transfer module 30 may include a transfer chamber 320 and a second transfer robot 340.

An inner atmosphere of the transfer chamber 320 may be maintained at a vacuum pressure. The second transfer robot 340 may be disposed in the transfer chamber 320. For example, the second transfer robot 340 may be disposed at a center of the transfer chamber 320. The second transfer robot 340 transfers the substrate between the load lock chamber 40 and the process chamber 50 to be described later. In addition, the second transfer robot 340 may transfer the substrate between the process chambers 50.

The second transfer robot 340 may move in a vertical direction (e.g., the third direction 6). The second transfer robot 340 may have a second transfer hand 342 which forwardly moves, backwardly moves, or rotates on the horizontal plane. The substrate is placed on a second transfer hand 342. The second transfer robot 340 may have a plurality of second transfer hands 342. The plurality of second transfer hands 342 may be disposed to be spaced apart from each other in the vertical direction.

At least one process chamber 50 to be described later may be connected to the transfer chamber 320. According to an embodiment, the transfer chamber 320 may have a polygonal shape. The load lock chamber 40 to be described later and the process chamber 50 to be described later may be disposed around the transfer chamber 320. For example, as shown in FIG. 1, a hexagonal transfer chamber 320 may be disposed at a center of the vacuum transfer module 30, and the load lock chamber 40 and the process chamber 50 may be disposed along its circumference. Unlike those mentioned above, the shape of the transfer chamber 320 and the number of process chambers 50 can be variously changed depending on user requirements or process requirements.

The load lock chamber 40 may be disposed between the transfer frame 220 and the transfer chamber 320. The load lock chamber 40 has a buffer space in which the substrate is exchanged between the transfer frame 220 and the transfer chamber 320. For example, a substrate on which a predetermined treatment is completed in the process chamber 50 may temporarily remain in the buffer space of the load lock chamber 40. In addition, the substrate, which is taken from the container F and which is scheduled for a predetermined treatment, may temporarily remain in the buffer space of the load lock chamber 40.

As described above, the inner atmosphere of the transfer frame 220 may be maintained at the atmospheric pressure, and the inner atmosphere of the transfer chamber 320 may be maintained at a vacuum pressure. Accordingly, the load lock chamber 40 is disposed between the transfer frame 220 and the transfer chamber 320, so that the inner atmosphere thereof can be switched between the atmospheric pressure and the vacuum pressure.

The process chamber 50 is connected to the transfer chamber 320. There may be a plurality of process chambers 50. The process chamber 50 may be a chamber which performs a predetermined process on the substrate. According to an embodiment, the process chamber 50 may treat the substrate using a plasma. For example, the process chamber 50 may be an etching process using the plasma to remove a thin film on the substrate, an ashing process to remove a photoresist film, a deposition process to form the thin film on the substrate, a dry cleaning process, an Atomic Layer Deposition (ALD) process to deposit an atomic layer on the substrate, or an Atomic Layer Etching (ALE) chamber to etch the atomic layer on the substrate. However, the inventive concept is not limited thereto, and a plasma treatment process performed in the process chamber 50 may be variously modified to a known plasma treatment process.

The process chamber 50 may perform a plasma treatment on the substrate. The process chamber 50 includes a housing 500, a support unit 600, a gas supply unit 700, and a shower head unit 800.

The housing 500 may have a shape in which an inside thereof is sealed. The housing 500 has a treating space 501 for treating the substrate therein. The treating space 501 may be maintained in a substantially vacuum atmosphere while treating the substrate. A material of the housing 500 may include a metal. According to an embodiment, the material of the housing 500 may include an aluminum. The housing 500 may be grounded.

A taking-in/out opening (not shown) may be formed on a sidewall of the housing 500. The taking-in/out opening (not shown) functions as a space in which the substrate is taken into or taken out of the treating space 501. The taking-in/out opening (not shown) may be selectively opened and closed by a door assembly which is not shown.

An exhaust hole 530 may be formed on a bottom surface of the housing 500. The exhaust hole 530 is connected to the exhaust line 540. A depressurizing member (not shown) may be installed in the exhaust line 540. The depressurizing member (not shown) may be any one of known pumps providing a negative pressure. A process gas and process impurities supplied to the treating space 501 may be discharged from the treating space 501 through the exhaust hole 530 and the exhaust line 540 sequentially. In addition, since the depressurizing member (not shown) provides the negative pressure, a pressure of the treating space 501 may be adjusted.

An exhaust baffle 550 functioning to more uniformly exhaust the treating space 501 may be disposed above the exhaust hole 530. The exhaust baffle 550 may be positioned between a sidewall of the housing 500 and a support unit 600 to be described later. The exhaust baffle 550 may have a substantially ring shape when viewed from above. At least one baffle hole 552 may be formed in the exhaust baffle 550. The baffle hole 552 may penetrate a top surface and a bottom surface of the exhaust baffle 550. A process gas and process impurities of the treating space 501 may flow to the exhaust hole 530 and the exhaust line 540 through the baffle hole 552.

The support unit 600 is disposed inside the housing 500. The support unit 600 may be disposed in the treating space 501. The support unit 600 may be disposed to be upwardly spaced apart from a bottom surface of the housing 500 by a predetermined distance. The support unit 600 supports the substrate. The support unit 600 may include an electrostatic chuck (ESC) which adsorbs the substrate using an electrostatic force. Alternatively, the support unit 600 may support the substrate using various methods such as a vacuum adsorption or a mechanical clamping. Hereinafter, the support unit 600 including the electrostatic chuck will be described as an example.

In an embodiment of the support unit 600, the support unit 600 may include an electrostatic chuck 610, a dielectric plate 620, a base plate 630, a ring member 640, an insulation plate 650, a bottom cover 660, a heating unit 670, and a cooling unit 680.

The electrostatic chuck 610 supports the substrate. The electrostatic chuck 610 may include a dielectric plate 620 and a base plate 630. The dielectric plate 620 is positioned at a top end of the support unit 600. The dielectric plate 620 may be a dielectric substance having a disk shape. The substrate is placed on a top surface of the dielectric plate 620. According to an embodiment, the top surface of the dielectric plate 620 may have a smaller radius than the substrate. If the substrate is placed on the top surface of the dielectric plate 620, an edge region of the substrate may be positioned outside the dielectric plate 620.

An electrode 621 and a heater 671 are disposed within the dielectric plate 620. According to an embodiment, the electrode 621 may be positioned above the heater 671 inside the dielectric plate 620. The electrode 621 is electrically connected to a first power source 621a. The first power source 621a may include a DC power source. A first switch 621b is installed between the electrode 621 and the first power source 621a. If the first switch 621b is turned on, the electrode 621 is electrically connected to the first power source 621a, and a DC current flows through the electrode 621. An electrostatic force is applied between the electrode 621 and the substrate by a current flowing through the electrode 621. Accordingly, the substrate is adsorbed on the dielectric plate 620.

At least one first fluid channel 623 may be formed inside the dielectric plate 620. The first fluid channel 623 may be formed from a top surface of the dielectric plate 620 to a bottom surface of the dielectric plate 620. The first fluid channel 623 communicates with a second fluid channel 633 to be described later. If viewed from above, the first fluid channel 623 may be formed to be spaced apart from each other in each of the central region of the dielectric plate 620 and the edge region surrounding the central region thereof. The first fluid channel 623 functions as a passage through which a heat transfer medium to be described later is supplied to a bottom surface of the substrate.

The base plate 630 is positioned below the dielectric plate 620. The base plate 630 may have a disk shape. A top surface of the base plate 630 may be stepped so that a central region thereof is positioned higher than an edge region. A central region of a top part of the base plate 630 may have an area corresponding to a bottom surface of the dielectric plate 620. The central region of the top surface of the base plate 630 may be adhered to a bottom surface of the dielectric plate 620. A ring member 640 to be described later may be positioned above the edge region of the base plate 630.

Also, the base plate 630 may include a conductive material. For example, a material of the base plate 630 may include an aluminum. The base plate 630 may be a metal plate. For example, an entire region of the base plate 630 may be a metal plate. The base plate 630 may be electrically connected to the third power source 630a. The third power source 630a may be a high frequency power source generating a high frequency power. For example, the high frequency power source may be an RF power source. The RF power source may be a high bias power RF power source. The base plate 630 receives a high frequency power from the third power source 630a. Accordingly, the base plate 630 may function as an electrode generating an electric field. According to an embodiment, the base plate 630 may function as a bottom electrode of a plasma source to be described later. However, the inventive concept is not limited thereto, and the base plate 630 may be grounded to function as a bottom electrode.

Also, a first circulation fluid channel 632 and a second circulation fluid channel 634 may be positioned within the base plate 630. In addition, a second fluid channel 633 may be formed inside the base plate 630.

The first circulation fluid channel 632 may be a passage through which a heat transfer medium circulates. The first circulation fluid channel 632 may have a spiral shape. The first circulation fluid channel 632 is in fluid communication with the second fluid channel 633 to be described later. In addition, the first circulation fluid channel 632 is connected to a first supply source 632a through a first supply line 632c.

The heat transfer medium is stored in the first supply source 632a. The heat transfer medium may include an inert gas. According to an embodiment, the heat transfer medium may include a helium (He) gas. However, the inventive concept is not limited thereto, and the heat transfer medium may include various types of gases or liquids. The heat transfer medium may be a fluid supplied to the bottom surface of the substrate to resolve a non-uniformity of a temperature of the substrate while performing a plasma treatment on the substrate. In addition, the heat transfer medium may serve as a medium for transferring a heat transferred from the plasma to the substrate, to the dielectric plate 620 and the ring member 640 to be described later from the substrate, while the plasma treatment is performed on the substrate.

A first valve 632b is installed in the first supply line 632c. The first valve 632b may be an opening/closing valve. As the first valve 632b is opened and closed, the heat transfer medium may be selectively supplied to the first circulation fluid channel 632.

The second fluid channel 633 fluidly communicates the first circulation fluid channel 632 with the first fluid channel 623. The heat transfer medium supplied to the first circulation fluid channel 632 may be supplied to the bottom surface of the substrate through the second fluid channel 633 and the first fluid channel 623 sequentially.

The second circulation fluid channel 634 may be a passage through which a cooling fluid circulates. The second circulation fluid channel 634 may have a spiral shape. In addition, the second circulation fluid channel 634 may be disposed such that ring-shaped fluid channels having different radii share the same center with each other. The second circulation fluid channel 634 is connected to the second supply source 681 through the second supply line 683.

The ring member 640 is disposed in an edge region of the electrostatic chuck 610. According to an embodiment, the ring member 640 may be a focus ring. The ring member 640 has a ring shape. The ring member 640 is disposed along a circumference of the dielectric plate 620. For example, the ring member 640 may be disposed above the edge region of the base plate 630.

A top surface of the ring member 640 may be formed to be stepped. According to an embodiment, an inner portion of the top surface of the ring member 640 may be positioned at the same height as the top surface of the dielectric plate 620. In addition, the inner portion of the top surface of the ring member 640 may support a bottom surface of the edge region of the substrate positioned outside the dielectric plate 620. An outer portion of the top surface of the ring member 640 may surround a side surface of the edge region of the substrate. In addition, for the ring member 640, a surface on which a step 640a is formed has a right angle or an obtuse angle with the top surface.

An insulation plate 650 is positioned above the base plate 630. The insulation plate 650 may include an insulating material. The insulation plate 650 electrically insulates the base plate 630 from a bottom cover 660 to be described later. The insulation plate 650 may have a substantially disk shape when viewed from above. The insulation plate 650 may have an area corresponding to that of the base plate 630.

The bottom cover 660 is positioned below the insulation plate 650. The bottom cover 660 may have a cylindrical shape with an open top surface when viewed from above. A top surface of the bottom cover 660 may be covered by the insulation plate 650. A lift pin assembly 661 for lifting and lowering the substrate may be positioned in an inner space of the bottom cover 660.

The bottom cover 660 may include a plurality of connection members 662. The connection member 662 may connect an outer surface of the bottom cover 660 to an inner wall of the housing 500. The plurality of connection members 662 may be disposed to be spaced apart along a circumferential direction of the bottom cover 660. The connection member 662 supports the support unit 600 within the housing 500. In addition, the connection member 662 may be connected to a grounded housing 500 to ground the bottom cover 660.

The connection member 662 may have a hollow shape having a space therein. The first power line 621c connected to the first power source 621a, the second power line 622c connected to the second power source 672, the third power line 630c connected to the third power source 630a, the first supply line 632c connected to the first circulation fluid channel 632, and the second supply line 683 connected to the second circulation fluid channel 634 extend to an outside of the housing 500 through an inner space of the connection member 662.

The heating unit 670 includes a heater 671, a second power source 672, a second switch 673, and a heating control unit 674.

The heater 671 is electrically connected to the second power source 672. The second switch 673 is installed between the heater 671 and the second power source 672. If the second switch 673 is turned on, the heater 671 may be electrically connected to the second power source 672. The heater 671 may generate a heat by resisting a current supplied from the second power source 672. The heat generated by the heater 671 is transferred to the substrate via the dielectric plate 620. The substrate placed on the dielectric plate 620 by the heat generated by the heater 671 may maintain a predetermined temperature. The heater 671 may include a spiral coil. In addition, the heater 671 may include a plurality of coils. Although not shown, the plurality of coils may be provided in different regions of the dielectric plate 620, respectively. For example, a coil for heating a central region of the dielectric plate 620 and a coil for heating an edge region may each be buried in the dielectric plate 620, and a degree of heat generation between the coils may be independently controlled. In the above-described example, the heater 671 is positioned within the dielectric plate 620, but the inventive concept is not limited thereto. For example, the heater 671 may not be positioned within inside the dielectric plate 620. In addition, in this embodiment, the heater 671, the second power source 672, and the second switch 673 which are electrically connected to each other are composed of multiple sets to heat the dielectric plate 620 by region by applying a heat by regions of the dielectric plate 620.

The heating control unit 674 is electrically connected to the second switch 673. The heating control unit 674 heats the heater 522 when controlling the second switch 673 to an on state, and turns off the heating of the heater 522 when controlled to an off state. Here, the heating control unit 674 controls the second switch 673 connected to each of the heaters 522 to selectively turn on the heaters 522 arranged at each region of the electrostatic chuck 610 of the support unit 600, to heat the temperature of the electrostatic chuck 610 by each region. In this case, the heating control unit 674 communicates with the temperature analysis unit 70 by a wireless communication and heats the temperature of the electrostatic chuck 610 by regions based on a temperature distribution information detected by the temperature analysis unit 70. For example, the heating control unit 674 turns on the heater 522 in a respective region so that only the respective region is heated if the temperature around a specific region of the electrostatic chuck 610 is lower than an average value or a set value among an acquired temperature distribution information.

The cooling unit 680 includes a second supply source 681, a second valve 682, a second supply line 683, and a cooling control unit 684.

A cooling fluid is stored in the second supply source 681. For example, the cooling fluid may be provided as cooling water. A cooler not shown may be provided to the second supply source 681. The cooler (not shown) may cool the cooling fluid to a predetermined temperature. However, unlike the above-described example, the cooler (not shown) may be installed in the second supply line 683.

The second valve 682 is installed between the second supply line 683. The second valve 682 may be an opening/closing valve which an opening/closing operation is performed by an electronic signal. An opening/closing state of the second valve 682 is controlled by the cooling control unit 684. In this case, the second valve 682 allows the cooling fluid to flow to the second supply line 683 when it is open, and prevents the cooling fluid from flowing to the second supply line 683 when it is closed.

The second valve 682 is installed in the second supply line 683. The cooling fluid may be selectively supplied to the second circulation fluid channel 634 according to an opening/closing of the second valve 682. The cooling fluid is supplied to the second circulation fluid channel 634 through the second supply line 683. The cooling fluid flowing through the second circulation fluid channel 634 may cool the base plate 630. The substrate may be cooled together via the base plate 630. In addition, as shown in the drawing, the second supply line 683 is composed of a plurality, and the second valves 682 are each installed at each of the plurality.

The cooling control unit 684 controls the opening/closing state of the second valve 682 to selectively supply cooling fluid to the second circulation fluid channel 634. A plurality of second circulation fluid channels 634 are formed, and second valves 682 are connected to each of the second circulation fluid channels 634. The cooling control unit 684 selectively controls the second valves 682 connected to the second circulation fluid channel 634 so that the cooling fluid flows each second circulation fluid channel 634, thereby cooling the base plate 630 by region. In this case, the cooling control unit 684 interacts with the temperature analysis unit 70 by a wireless communication and cools a temperature of the base plate 630 by regions based on a temperature information detected by the temperature analysis unit 70.

The gas supply unit 700 supplies a process gas to the treating space 501. The gas supply unit 700 may include a gas supply nozzle 710, a gas supply line 720, and a gas supply source 730.

The gas supply nozzle 710 may be installed in a central region of a top surface of the housing 500. An injection hole is formed on a bottom surface of the gas supply nozzle 710. The injection port (not shown) may inject the process gas into the housing 500.

An end of the gas supply line 720 is connected to the gas supply nozzle 710. The other end of the gas supply line 720 is connected to the gas supply source 730. The gas supply source 730 may store the process gas. The process gas may be a gas which is excited in a plasma state by a plasma source to be described later. According to an embodiment, the process gas may include an NH₃, an NF₃, and/or an inert gas.

A gas valve 740 is installed in the gas supply line 720. The gas valve 740 may be an opening/closing valve. The process gas may be selectively supplied to the treating space 501 according to the opening and closing of the gas valve 740.

The plasma source excites the process gas supplied into the housing 500 into a plasma state. A Capacitive Coupled Plasma (CCP) is used as the plasma source in accordance with an embodiment of the inventive concept. However, the inventive concept is not limited thereto, and the process gas supplied to the treating space 501 may be excited into a plasma state using an inductively coupled plasma (ICP) or a microwave plasma. Hereinafter, a case in which capacitance-coupled plasma (CCP) is used as a plasma source according to an embodiment will be described as an example.

The plasma source may include a top electrode and a bottom electrode. The top electrode and the bottom electrode may be disposed to face each other within the housing 500. One of both electrodes may apply a high-frequency power, and the other electrode may be grounded. Alternatively, the high frequency power may be applied to both electrodes. An electric field is formed in a space between both electrodes, and the process gas supplied to the space may be excited in a plasma state. A substrate treating process is performed using the plasma. According to an embodiment, the top electrode may be an electrode plate 830 to be described later, and the bottom electrode may be the base plate 630 described above.

The shower head unit 800 is positioned above the support unit 600 within the housing 500. The shower head unit 800 may include a shower plate 810 and a support portion 820.

The shower plate 810 is positioned on a top side of the support unit 600 to face the support unit 600. The shower plate 810 may be positioned to be downwardly spaced apart from a ceiling surface of the housing 500. According to an embodiment, the shower plate 810 may have a disk shape having a constant thickness. The shower plate 810 is disposed to be downwardly spaced apart from the ceiling surface of the housing 500 by a predetermined distance, and a space may be formed between the shower plate 810 and the ceiling surface of the housing 500. In addition, a plurality of holes 811 are formed in the shower plate 810. The plurality of holes 811 disperse and pass the process gas supplied from the gas supply nozzle 710.

In addition, a material of the shower plate 810 may include a metal. The shower plate 810 may be grounded. In the embodiment, the shower plate 810 is used as a top electrode. However, in the inventive concept, the shower plate 810 is not limited to being used only as the top electrode, and the top electrode may be installed as a separate electrode member.

The support portion 820 supports a side portion of the shower plate 810 and a side portion of the electrode plate 830, respectively. A top end of the support portion 820 is connected to a ceiling surface of the housing 500, and a bottom portion of the support portion 820 is connected to a side portion of the shower plate 810 and a side portion of the electrode plate 830, respectively. A material of the support portion 820 may include a non-metal.

The process control unit 60 connects with the load port 10, the atmospheric pressure transfer module 20, the vacuum transfer module 30, the load lock chamber 40, and the process chamber 50, and sets and manages a schedule for a transfer driving of the substrate input to the load port 10, the atmospheric pressure transfer module 20, the vacuum transfer module 30, the load lock chamber 40, and the process chambers 50, and sets and manages a process schedule of the process chamber 50.

In addition, the process control unit 60 receives the temperature distribution information by wireless communication with the temperature analysis unit 70 and transmits an input temperature distribution information to the process chamber 50. The process chamber 50 input with the temperature distribution information transmits the temperature distribution information to the heating control unit 674 and the cooling control unit 684, and the heating control unit 674 and the cooling control unit 684 input with the temperature distribution information heats or cools the support unit 600 based on the temperature distribution information by region. Here, the process control unit 60 is formed including a wireless communication unit to wirelessly receive the temperature distribution information from the temperature analysis unit 70, and communicates with the temperature analysis unit 70 through a short-range wireless communication such as a Bluetooth, a Zigbee, a Wireless LAN (Wifi), an IrDA, or a HomeRF, etc.

The temperature analysis unit 70 is a device which measures a temperature of each region of the support unit 600 by seating on the support unit 600 of the process chamber instead of the substrate. Here, the temperature analysis unit 70 may be seated on the support unit 600 instead of the substrate, which is a wafer, through the second transfer robot 340 of the vacuum transfer module 30. The temperature analysis unit 70 measures a surface temperature of each region of the support unit 600 according to a cycle or a planned schedule without stopping an operation of the process chamber. In the inventive concept, the temperature analysis unit 70 measures the surface temperature of the support unit 600 with respect to the electrostatic chuck 610 for each region. In addition, in order not to stop the operation of the process chamber 50, the temperature analysis unit 70 is put into the process chamber 50 instead of the substrate put into the process chamber to measure the temperature distribution information for each region of the support unit 600. In addition, the temperature analysis unit 70 transmits the temperature distribution information by performing the above-described wireless communication with the process control unit 60. In this case, if placed in the process chamber 50, the temperature analysis unit 70 is sealed by the process chamber 50 and a wireless communication is impossible, so if transferred to the vacuum transfer module 30, it can wirelessly communicate with the process control unit 60 to transmit the temperature distribution information.

As an embodiment of such a temperature analysis unit 70, the temperature analysis unit 70 can be formed including a temperature measurement module 71, a temperature analysis module 72, and a coupling body 73.

The temperature measurement module 71 detects the temperature information by measuring the surface temperature of the support unit for each region while seated on the support unit. As an embodiment of the temperature measurement module 71, the temperature measurement module 71 may include a temperature sensor 71a and a sensor-side circuit board 71b.

A plurality of temperature sensors 71a are formed, and are disposed to be spaced apart from each other. As illustrated, dozens of temperature sensors 71a are configured and may be disposed to be spaced apart from each other. In this case, the temperature sensor 71a is selected as at least one among a surface elastic wave (SAW) temperature sensor, an RTD sensor, and a thermistor. Here, if the temperature sensor 71a is composed of a surface elastic wave temperature sensor, a temperature value of the support unit 600 may be obtained at a high response speed. In addition, if the temperature sensor 71a is composed of an RTD sensor and a thermistor, the temperature value can be measured up to hundreds of degrees (C). In addition, if the temperature sensor 71a is composed of a surface elastic wave temperature sensor, the RTD sensor which is measured locally and a temperature in a wider region than the thermistor can be measured.

In this case, some of the temperature sensors 71al among the plurality of temperature sensors 71a may be set to measure the surface temperature of the support unit 600, and the remaining temperature sensors 71a2 aside from the temperature sensors 71a measuring the surface temperature may be set to measure an inner temperature of the support unit 600. At this time, the temperature sensor 71a which measures the surface temperature of the support unit 600 and the temperature sensor 71a which measures the inner temperature of the support unit 600 may be set in different types as necessary. For example, the temperature sensor 71a which measures the surface temperature of the support unit 600 may consist of a surface elastic wave temperature sensor, and the temperature sensor 71a which measures the inner temperature of the support unit 600 may consist of an RTD sensor. Therefore, the temperature sensor 71a is composed of different types, and the range of temperatures which can be measured and a response speed until the temperature is measured are set differently, so the surface temperature and the inner temperature can be measured separately.

The sensor-side circuit board 71b is formed in a plate shape to provide a region in which the temperature sensors 71a are to be mounted. In this case, the sensor-side circuit board 71b has a circuit pattern in which each of the temperature sensors 71a is electrically connected. Here, the temperature sensor 71a may be soldered to the circuit pattern of the sensor-side circuit board 71b or coupled in a state of mechanical contact with the circuit pattern. In addition, the sensor-side circuit board 71b settles on the support unit 600 when measured, and when seated on the support unit 600, the temperature sensor 71a approaches the surface of the support unit 600. Here, the sensor-side circuit board 71b is configured in a size which covers the top surface of the support unit 600 to measure the surface temperature of the support unit 600. Accordingly, the sensor-side circuit board 71b is manufactured in various sizes depending on the size of the support unit 600. For example, the sensor-side circuit board 71b can be manufactured in different sizes depending on the size of a support unit 600 for seating a substrate with a diameter of 300 mm and a size of a support unit 600 for seating a substrate with a diameter of 200 mm.

In addition, the sensor-side circuit board 71b further has an putting direction checking region for checking an putting direction. In this embodiment, the putting direction checking region 71g is formed in a notch shape, and the putting direction checking region 71g is not limited to a notch shape, and may be formed in various shapes such as a shape printed on the sensor side circuit board 71b or a protruding shape. The putting direction checking region 71g of the sensor-side circuit board 71b is used to determine a position at which the temperature analysis unit 70 is input by the first transfer robot 240 and the second transfer robot 340. In this way, since the temperature analysis unit 70 is always input in a certain direction by the putting direction checking region 71g, temperature sensors 71a can also measure the temperature of the support unit 600 at a designated position. Therefore, the temperature distribution information with respect to a plane of the support unit 600 analyzed by the temperature analysis unit 70 can specify the temperature value for which position of the support unit 600.

The temperature analysis module 72 is input with the temperature information in communication with the temperature measurement module 71, analyzes the input temperature information by region and converts it into the temperature distribution information, and transmits a converted temperature distribution information to the process chamber 50. In this case, the temperature analysis module 72 is combined with the temperature measurement module 71 to be seated on the support unit 600 instead of the substrate, and is seated on the support unit 600 by the second transfer robot 340 along with the temperature measurement module 71.

As an embodiment of such a temperature analysis module 72, the temperature analysis module 72 may include a temperature analysis circuit unit 72a, a module-side communication unit 72b, a battery 72c, an analysis-side circuit board 72d, and a connection unit 72e.

The temperature analysis circuit unit 72a is electrically connected to the temperature sensors 71a to analyze the temperature information detected by the temperature sensors 71a to generate a temperature distribution information for each region of the support unit 600. Here, the temperature distribution information is an information in which the temperature information is recorded for each coordinate value on a circular plane coordinate seen from a top to a bottom of the electrostatic chuck 610. In this case, the temperature information recorded for each plane coordinate value is numerically interpolated by a preset numerical interpolation program and generated as temperature distribution information on a two-dimensional plane. Therefore, based on the temperature information detected by each of the temperature sensors 71a, the temperature analysis circuit unit 72a can obtain the temperature value for each position within the entire region of the top surface of the electrostatic chuck 610.

The module-side communication unit 72b is a device which performs a short-range wireless communication such as a Bluetooth, a Zigbee, a Wireless LAN (Wifi), an IrDA, or a HomeRF. The module-side communication unit 72b may be installed by being soldered or mechanically coupled to the analysis-side circuit board 72d. The module-side communication unit 72b is electrically connected to the temperature analysis circuit unit 72a and connected with the temperature analysis circuit unit 72a. The module-side communication unit 72b connected to the temperature analysis circuit unit 72a is input with the temperature distribution information from the temperature analysis circuit unit 72a and transmits the input temperature distribution information to the process control unit 60. Such a module-side communication unit 72b is put in place of the substrate to form a state in which a temperature analysis unit 70 which cannot be connected by wire can be wirelessly communicated.

The battery 72c is electrically connected to the temperature analysis circuit unit 72a and the module side communication unit 72b, and supplies a power to the temperature analysis circuit unit 72a and the module side communication unit 72b. In addition, the battery 72c is installed on the analysis side circuit board 72d. Such a battery 72c is installed on the analysis circuit board along with the temperature analysis circuit unit 72a and the module side communication unit 72b to supply the power to the temperature analysis circuit unit 72a and the module side communication unit 72b. Therefore, the temperature analysis unit 70 which is not connected by wire can analyze the temperature of the support unit 600 while moving in the process with the substrates.

The analysis-side circuit board 72d includes a temperature analysis circuit unit 72a, a module-side communication unit 72b, and a battery 72c. The analysis side circuit board 72d has a circuit pattern which electrically connects the temperature analysis circuit unit 72a, the module side communication unit 72b, and the battery 72c. The analysis side circuit board 72d provides a region to be fixed while the temperature analysis circuit unit 72a, the module side communication unit 72b, and the battery 72c are electrically connected to each other.

The connection unit 72e electrically connects the analysis side circuit board 72d and the temperature measurement module 71. In this case, the connection unit 72e can be formed as a contact terminal or a wiring connector which electrically contacts the analysis side circuit board 72d and the sensor side circuit board 71b. The connection unit 72e electrically connects the temperature measurement module 71 and the temperature analysis module 72 if the temperature measurement module 71 and the temperature analysis module 72 are coupled, and disconnects an electrical connection between the temperature measurement module 71 and the temperature analysis module 72 if the temperature measurement module 71 and the temperature analysis module 72 are un-coupled. This connection unit 72e maintains the electrical connection between the temperature measurement module 71 and the temperature analysis module 72 even when the temperature measurement module 71 and the temperature analysis module 72 are combined and transferred.

The coupling body 73 detachably couples the temperature measurement module 71 and the temperature analysis module 72. As an embodiment of such a coupling body 73, the coupling body 73 can be configured in a form which screws the temperature measurement module 71 and the temperature analysis module 72 with bolts. However, in the inventive concept, a configuration of the coupling body 73 is not limited to bolts and screws, and the coupling body 73 can be implemented by various modifications between the temperature measurement module 71 and the temperature analysis module 72 by a hook-coupling, a pin-coupling, or an insertion-coupling, etc. In this way, the coupling body 73 allows the temperature measurement module 71 and the temperature analysis module 72 to be easily coupled and separated when replacing the temperature measurement module 71 according to a size of the support unit 600.

Meanwhile, the coupling body 73 which couples the temperature analysis module 72 and the temperature measurement module 71 allows a coupling position of the temperature analysis module 72 and the temperature measurement module 71 to be at a certain position, and so an arrangement direction of the temperature analysis module 72 may face a certain direction from the support unit 600. Here, if the arrangement direction of the temperature analysis module 72 is varied and arranged in various directions in the support unit 600, the size and direction of a magnetic field applied within the housing 500 may also vary depending on the arrangement direction, and a shape of noise may vary. If noises of different sizes are generated depending on the arrangement direction of the temperature analysis module 72, variables such as mistaking a noise for a signal value may be caused during a signal processing of the temperature analysis module 72.

Accordingly, a plurality of coupling bodies 73 are spaced apart from each other, and one of the plurality of coupling bodies 73 can be configured to have a different binding method than the other coupling bodies 73, so that the coupling position of the coupling bodies 73 are only at a specific position. For example, as described in FIG. 6, if the coupling body 73 consists of a first coupling body 73a and a second coupling body 73b in which a bolt and a nut are coupled, a top end of the first coupling body 73a may be formed to be attachable/detachable to the temperature measurement module 71 while coupled to the temperature analysis module 72, and a bottom end of the second coupling body 73b may be formed to be attachable/detachable to the temperature analysis module 72 while coupled to the temperature measurement module 71. As shown in this example, the coupling body 73 may be configured in a plurality, and among the plurality, a coupling method of any one may be formed different from a coupling method from the rest, and a coupling of the temperature analysis module 72 and the temperature measurement module 71 can always be combined only at a specific position.

For another example, as described in FIG. 7, if a third coupling body 73c and a fourth coupling body 73d in a bolt and nut form are configured above the temperature measurement module 71, a first hole which is a first coupling region 72d1 and a second hole which is a second coupling region 72d2 may be further formed at the temperature analysis module 72. Here, an inner diameter of the first coupling region 73d1 is formed to correspond to a diameter of the third coupling body 73c, and an inner diameter of the second coupling body 72d2 is formed to correspond to a diameter of the fourth coupling body 73d. Therefore, because the diameter of the third coupling body 72d1 corresponds to the diameter of the third coupling body 73c, it may be inserted to the first hole which is the first coupling region 72dl, but cannot be inserted to the second hole which is the second coupling region 72d2. Therefore, since the diameter of the third coupling body 73c is formed larger than the diameter of the fourth coupling body 73d, it can be inserted into the first hole, which is the first coupling region 72dl, but cannot be inserted into the second hole, which is the second coupling region 72d2. In this way, the temperature analysis module 72 and the temperature measurement module 71 can always be coupled only at a specific position by disposing the coupling body 73 in a plurality and forming different diameters and bonding only in a bonding region which that matches a diameter. Here, it may be modified so the top part of the third coupling body 73c and the top part of the fourth coupling body 73d are coupled to the temperature analysis module 72, and the first hole which is the first coupling region 72d1 and the second hole which is the second coupling region 72d2, which are inserted corresponding to the third coupling body 73c and the fourth coupling body 73d, may be formed in the temperature measurement module 71.

Hereinafter, a substrate treating method using the substrate treating apparatus according to an embodiment of the inventive concept as described above will be described.

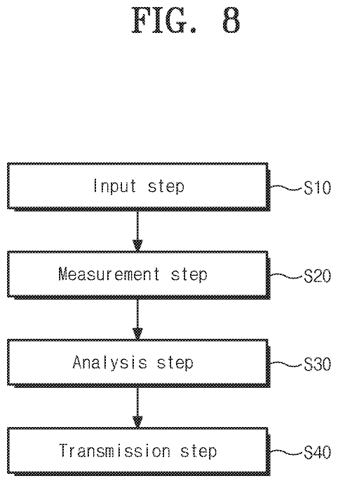

FIG. 8 is a flowchart of the substrate treating method according to an embodiment of the inventive concept.

Referring further to FIG. 8, the substrate treating method according to an embodiment of the inventive concept includes an input step S10, a measurement step S20, an analysis step S30, and a transmission step S40.

The input step S10 is a step of inputting the temperature analysis unit 70 instead of the substrate. First, in the input step S10, the temperature measurement module 71 suitable for the size of the support unit 600 is prepared, and a prepared temperature measurement module 71 is coupled to the temperature analysis module 72 with the coupling body 73 and installed on a container. In this case, the temperature analysis module 72 is driven by independently receiving a power by the battery 72c. Next, in the input step S10, the container on which the temperature analysis unit 70 is mounted is loaded into the first transfer robot 240 of an atmospheric pressure transfer module 20 while being mounted on the load port 10. In this case, a center of the temperature analysis unit 70 loaded on the first transfer robot 240 may be aligned by an aligner. Next, in the input step S10, the first transfer robot 240 transfers it to the load lock chamber 40, and the second transfer robot 340 transfers the temperature analysis unit 70 in the load lock chamber 40 to the vacuum transfer module 30. Next, in the input step S10, the temperature analysis unit 70 transferred to the vacuum transfer module 30 is seated in the support unit 600 of the process chamber 50. At this time, the temperature analysis unit 70 is arranged based on a notch-shaped putting direction checking region 71g, so the temperature analysis module 72 and the temperature measurement module 71 are always aligned in a certain direction. Therefore, since the temperature analysis unit 70 is maintained in a certain direction, it is possible to specify the position value of the temperature distribution information for the support unit 600. In this case, since the temperature analysis module 72 is always coupled with the temperature measurement module 71 at a specific position, variables which mistake a noise for signal values can be blocked in advance according to a change in the arrangement direction of the temperature analysis module 72 during a signal processing.

Next, in the measurement step S20, the temperature analysis unit 70 seated on the support unit 600 measures the temperature of the support unit 600 and generates the temperature information for each region of the support unit 600. In this case, the temperature analysis unit 70 can generate the temperature information for each region of the support unit 600 while the plurality of temperature sensors 71a are spaced apart from each other as described above. In this case, the measurement step S20 proceeds in a closed state in the process chamber 50, and the wireless communication between the temperature analysis unit 70 and the process control unit 60 is cut off.

Next, in the analysis step S30, the temperature analysis unit 70 analyzes the temperature of the support unit 600 and generates the temperature distribution information for each region of the support unit 600. In this case, as described above, the temperature analysis circuit unit 72a analyzes the temperature distribution of the support unit 600 on a plane coordinate by numerically interposing the temperature information detected by the temperature sensors 71a.

Next, in the transmission step S40, the second transfer robot 340 transfers the temperature analysis unit 70 to the vacuum transfer module 30, outside of the process chamber 50. At this time, the temperature analysis unit 70 is transferred to the vacuum transfer module 30 outside the process chamber 50 shielding the wireless communication to activate the wireless communication and transmit an analyzed temperature distribution information to the process control unit 60. Then, the process control unit 60, which receives the temperature distribution information, transmits the temperature distribution information to the heating control unit 674 and the cooling control unit 684 of the process chamber 50. After that, the heating control unit 674 and the cooling control unit 684 perform a control driving to heat or cool the support unit 600 by region based on the temperature distribution information.

Next, the temperature analysis unit 70 which has completed the transmission step S40 is input into the other process chambers 50 by the second transfer robot 340 of the vacuum transfer module 30, to perform the measurement step S20, the analysis step S30, and the transmission step S40 as aforementioned, and at each process chamber 50, a heating temperature and a cooling temperature of the support unit 600 is controlled by region based on the temperature distribution information transmitted through the temperature analysis unit 70.

In this way, the substrate treating apparatus and substrate treating method according to an embodiment of the inventive concept obtain the temperature distribution information in real time at an end of a process and apply it to the process, greatly reducing a time to analyze the temperature of the electrostatic chuck 610, and a possibility of a data error also is greatly reduced.

In addition, the substrate treating apparatus and substrate treating method according to an embodiment of the inventive concept can prevent analysis errors by an operator because the temperature analysis unit 70 immediately acquires and analyzes the temperature without the operator taking out the temperature analysis unit 70 to analyze the temperature.

In addition, the substrate treating apparatus and substrate treating method according to an embodiment of the inventive concept can change the temperature measurement module 71 depending on the size of the electrostatic chuck 610, which is the support unit 600, which improves an applicability and reduces a temperature measuring price.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a process chamber including a housing at which a treating space is formed for process treating a substrate and a support unit positioned at the treating space and configured to support the substrate; and
a temperature analysis unit configured to detect a temperature information of the support unit while mounted on the support unit and transmitting a detected temperature information to the process chamber, and
wherein the process chamber controls a temperature of the support unit based on the temperature information.

2. The substrate treating apparatus of claim 1, wherein the temperature analysis unit detects the temperature information while mounted on the treating space instead of the substrate.

3. The substrate treating apparatus of claim 1, wherein the support unit includes an electrostatic chuck for sucking the substrate with an electrostatic force, and
wherein the temperature analysis unit detects the temperature information of the electrostatic chuck.

4. The substrate treating apparatus of claim 3, wherein the temperature analysis unit detects the temperature information of the electrostatic chuck by regions.

5. The substrate treating apparatus of claim 4, wherein the process chamber further includes a heating unit configured to heat the electrostatic chuck by regions, and
wherein the temperature analysis unit transmits a detected temperature information to the heating unit, and
the heating unit heats the electrostatic chuck by regions based on the temperature information.

6. The substrate treating apparatus of claim 1, wherein the process chamber blocks a communication between the temperature analysis unit positioned at the treating space and the process chamber when switching to a closed state.

7. The substrate treating apparatus of claim 1, wherein the temperature analysis unit includes:
a temperature measurement module which measures a surface temperature of the support unit by regions while mounted on the support unit to detect the temperature information; and
a temperature analysis unit configured to connect with the temperature measurement module to be input with the temperature information, to analyze an input temperature information by region to change to a temperature distribution information, and to transfer a changed temperature distribution information to the process chamber.

8. The substrate treating apparatus of claim 7, wherein the temperature measurement module includes:
a temperature sensor disposed in a plurality which are spaced apart from one another; and
a sensor side circuit board on which the temperature sensor is installed on which a circuit pattern electrically connected to each of the temperature sensors is formed, and which is mounted on the support unit.

9. The substrate treating apparatus of claim 8, wherein the temperature sensor is chosen among any one of a surface elastic wave temperature sensor, an RTD sensor, or a thermistor.

10. The substrate treating apparatus of claim 9, wherein a portion of the plurality of the temperature sensors are set to measure a surface temperature of the support unit, and a portion of the temperature sensors aside from a temperature sensor measuring the surface temperature is set to measure an inner temperature of the support unit.

11. The substrate treating apparatus of claim 8, wherein the temperature analysis module includes:
a temperature analysis circuit unit configured to electrically connect with the temperature sensors and analyze a temperature information detected by the temperature sensors to generate a temperature distribution information by regions of the support unit;
a module side communication unit configured to connect with the temperature analysis circuit unit, to be input with the temperature distribution information from the temperature analysis circuit unit, and to wirelessly transmit an input temperature distribution information to the process chamber;
a battery electrically connected to the temperature analysis circuit unit and the module side communication unit, and supplying a power to the temperature analysis unit circuit unit and the module side communication unit; and
an analysis side circuit board on which the temperature analysis circuit unit, the module side communication unit and the battery are installed, and on which a circuit pattern electrically connecting the temperature analysis circuit unit, the module side communication unit, and the battery is formed.

12. The substrate treating apparatus of claim 11, wherein the temperature analysis module further includes a connection unit configured to electrically connect the analysis side circuit board and the temperature measurement module.

13. The substrate treating apparatus of claim 7, wherein the temperature analysis unit further includes a coupling body coupling the temperature measurement module and the temperature analysis unit in an attachable/detachable manner.

14. The substrate treating apparatus of claim 13 further comprising:
a load port at which the temperature analysis unit is put;
an atmospheric pressure transfer module positioned at a side of the load port and which transfers the temperature analysis unit within the load port in an atmospheric pressure state;
a load lock chamber positioned at a side of the atmospheric pressure transfer module, which transduces an atmospheric pressure to a vacuum pressure, and forms a space at which the temperature analysis unit is transferred; and
a vacuum transfer module which forms a vacuum pressure state, which transfers the temperature analysis unit positioned at the atmospheric pressure transfer module to the load lock chamber, and which mounts a transferred temperature analysis unit on the support unit of the process chamber, and
wherein the sensor side circuit board further includes an putting direction confirmation region for checking an putting direction,
the atmospheric pressure transfer module mounts the temperature analysis unit on the support unit so the putting direction confirmation region faces a certain direction, and
the coupling body is disposed in a plurality and any one coupling method among the plurality is formed differently so the temperature measurement module and the temperature analysis module are coupled only at a specific position.

15.-19. (canceled)

20. A substrate treating apparatus comprising:
a process chamber including a housing at which a treating space is formed for process treating a substrate, a support unit positioned at the treating space to support the substrate and including an electrostatic chuck for sucking the substrate, and a heating unit configured to heat the electrostatic chuck by regions based on a temperature information; and
a temperature analysis unit configured to detect a temperature information of the electrostatic chuck by regions while mounted on the support unit, transmitting a detected temperature information to the process chamber, and detecting the temperature information while mounted in the treating space instead of the substrate;
a load port at which the temperature analysis unit is put;
an atmospheric pressure transfer module positioned at a side of the load port and which transfers the temperature analysis unit within the load port in an atmospheric pressure state;
a load lock chamber positioned at a side of the atmospheric pressure transfer module, which transduces an atmospheric pressure to a vacuum pressure, and forming a space at which the temperature analysis unit is transferred; and
a vacuum transfer module which forms a vacuum pressure state, which transfers through the load lock chamber if the temperature analysis unit is positioned at the atmospheric pressure transfer module, and which mounts a transferred temperature analysis unit on the support unit of the process chamber so an putting direction confirmation region of the temperature analysis unit faces a certain direction, and
wherein the temperature analysis unit includes:
a temperature measurement module including a temperature sensor chosen among any one of a surface elastic wave temperature sensor, an RTD sensor, or a thermistor, disposed in a plurality which are spaced apart from one another, which measures a surface temperature of the support unit by regions to detect the temperature information, a portion of the plurality of the temperature sensors are set to measure the surface temperature of the support unit and at least other portion of the temperature sensors are set to measure an inner temperature of the support unit measuring the surface temperature and a sensor side circuit board on which the temperature sensor is installed, on which a circuit pattern electrically connected to each of the temperature sensors is formed, which is mounted on the support unit, and on which an putting direction confirmation region to check an putting direction is formed; and
a temperature analysis circuit unit configured to electrically connect with the temperature sensors and analyze a temperature information detected by the temperature sensors to generate a temperature distribution information by regions of the support unit, a module side communication unit configured to connect with the temperature analysis circuit unit, to be input with the temperature distribution information from the temperature analysis circuit unit, and to wirelessly transmit an input temperature distribution information to the process chamber, a battery electrically connected to the temperature analysis circuit unit and the module side communication unit, and supplying a power to the temperature analysis unit circuit unit and the module side communication unit, and an analysis side circuit board on which the temperature analysis circuit unit, the module side communication unit and the battery are installed, and on which a circuit pattern electrically connecting the temperature analysis circuit unit, the module side communication unit, and the battery is formed, a connection unit configured to electrically connect the analysis side circuit board and the temperature measurement module, and
a coupling body coupling the temperature measurement module and the temperature analysis unit in an attachable/detachable manner, which is disposed in a plurality and any one coupling method among the plurality is formed differently so the temperature measurement module and the temperature analysis module are coupled only at a specific position.
